(19) United States
(12) Patent Application Publication
(10) Pub. No.: US 2025/0115751 A1
(43) Pub. Date: Apr. 10, 2025

(54) THERMOSETTING COMPOSITIONS, CURED COMPOSITIONS, AND PREPREGS AND LAMINATES BASED ON SAME

(71) Applicant: ISOLA USA CORP., CHANDLER, AZ (US)

(72) Inventor: Teck Kai Wong, Singapore (SG)

(21) Appl. No.: 18/905,430

(22) Filed: Oct. 3, 2024

Related U.S. Application Data
(60) Provisional application No. 63/588,417, filed on Oct. 6, 2023.

(51) Int. Cl. C08L 25/14; C08J 5/24; C08K 5/42; C08K 5/5397; C08K 7/18; C08K 13/04; H05K 1/03

(52) U.S. Cl. CPC C08L 25/14; C08J 5/249; C08K 13/04; H05K 1/0366; C08J 2325/14; C08J 2461/14; C08J 2463/02; C08J 2463/04; C08K 5/42; C08K 5/5397; C08K 7/18; C08K 2201/005; C08L 2201/02; C08L 2205/025; C08L 2205/035

(57) ABSTRACT

This disclosure relates to thermosetting compositions suitable for use in making electronic materials such as circuit board substrates, as well as cured compositions, prepregs and laminates based on such thermosetting compositions. One aspect of the disclosure is a thermosetting composition comprising: an aromatic epoxy resin component; a poly(styrene-co-maleic anhydride) component; a maleimide-bearing oligomer component; the maleimide-bearing oligomer component having an average of at least 4 maleimides per molecule, on a number average, and a softening point of no more than 100° C.; a benzoxazine/maleimide component, that is a bis(benzoxazine) subcomponent and a bis(maleimide) subcomponent, and/or a reaction product thereof; an aromatic primary diamine component; microparticulate silica; an organic halogen-free fire retardant component; an effective amount of one or more catalysts.

### CROSS-REFERENCE TO RELATED APPLICATIONS

This application claims priority to U.S. provisional application No. 63/588,417, filed Oct. 6, 2023, which is incorporated by reference herein in its entirety.

### BACKGROUND OF THE DISCLOSURE

### 1. Field of the Disclosure

This disclosure relates to thermosetting compositions suitable for use in making electronic materials such as circuit board substrates, as well as cured compositions, prepregs and laminates based on such thermosetting compositions.

### 2. Technical Background

Prepregs and copper clad laminates are planar materials that are routinely used in the manufacture of printed circuit boards. Prepregs and laminates are typically composite structures that include a reinforcing material such as woven glass, non-woven glass, paper, or other fibrous and non-fibrous materials and a polymeric resin that is used as a matrix material-a material that is applied to or used to impregnate the reinforcing material.

With operating frequencies o f electronic devices ever increasing, the electrical properties of the prepregs and laminates are ever more important to carefully control. The electrical performance of the board involves various parameters, including dielectric constant (Dk), dielectric loss tangent (Df), insulation resistance, surface resistance, volume resistance, arc resistance, CTI or comparative tracking index, and electric strength.

But electrical performance is not the only necessary performance criterion. Rather, variety of other properties are necessary These include resistance to chemical reagents, thermal properties like glass transition temperature, dimensional stability, and Z-axis coefficient of thermal expansion; mechanical properties like strength and dimensional stability, adhesion to copper foil (as measured by peel strength).

Moreover, fire resistance is a highly desirable property of these materials. Many conventional fire retardants are halogenated compounds. But it is highly desirable in the marketplace to provide fire retardance without the use of halogenated compounds.

What are needed are new materials that have not only have good dielectric properties, especially at high frequencies, but also good performance with respect to various of these other properties.

### SUMMARY OF THE DISCLOSURE

One aspect of the disclosure is a thermosetting composition comprising:
an aromatic epoxy resin component, present in a total amount in the range of 5-25 wt %;
a poly(styrene-co-maleic anhydride) component, in an amount in the range of 8-30 wt %;
a maleimide-bearing oligomer component, in an amount in the range of 2-10 wt %, the maleimide-bearing oligomer component having an number-average of at least 3 maleimides per molecule, on a number average, and a softening point of no more than 100° C.;
a benzoxazine/maleimide component, that is a bis(benzoxazine) subcomponent and a bis(maleimide) subcomponent, and/or a reaction product thereof, present in an amount in the range of 2-20 wt %;
an aromatic primary diamine component, present in an amount of 0.1-2 wt %;
microparticulate silica, in an amount in the range of 15-50 wt %;
an organic halogen-free fire retardant component, in an amount of 3-25 wt %; and
an effective amount of one or more catalysts.

Another aspect of the disclosure is a cured (e.g., partially cured or substantially fully cured) product of a thermosetting composition as described herein.

Another aspect of the disclosure is a method for curing a thermosetting composition as described herein, the method comprising heating the thermosetting composition at a temperature of 150-250° C.

Another aspect of the disclosure is a prepreg comprising a mesh substrate at least partially embedded in a cured product as described herein.

Another aspect of the disclosure is a laminate of a plurality of prepregs as described herein.

### BRIEF DESCRIPTION OF THE DRAWINGS

FIG. 1 is a schematic cross-sectional view of a prepreg according to one embodiment of the disclosure.

FIG. 2 is a schematic cross-sectional view of a laminate according to one embodiment of the disclosure.

### DETAILED DESCRIPTION

The present inventors have developed particular thermosetting compositions that can provide excellent dielectric properties at high frequency, as well as good thermal properties and peel strength properties.

One aspect of the disclosure is a thermosetting composition comprising:
an aromatic epoxy resin component, present in a total amount in the range of 5-25 wt %;
a poly(styrene-co-maleic anhydride) component, in an amount in the range of 8-30 wt %;
a maleimide-bearing oligomer component, in an amount in the range of 2-10 wt %, the maleimide-bearing oligomer component having an average of at least 4 maleimides per molecule, on a number average, and a softening point of no more than 100° C.;
a benzoxazine/maleimide component, that is a bis(benzoxazine) subcomponent and a bis(maleimide) subcomponent, and/or a reaction product thereof, present in an amount in the range of 2-20 wt %;
an aromatic primary diamine component, present in an amount of 0.1-2 wt %;
microparticulate silica, in an amount in the range of 15-50 wt %;
an organic halogen-free fire retardant component, in an amount of 3-25 wt %; and
an effective amount of one or more catalysts.

As used herein, a thermosetting composition is a substantially liquid composition that cures from a liquid state to a solid state under the influence of heat. Various especially desirable thermosetting compositions are those that are “B-stageable,” that is, they can be partially cured to a manipulable solid under a first heat treatment, then later fully cured under a second heat treatment. The partially cured material can be, for example, in a so-called “B-stage,” and can be further cured to a so-called “C-stage.” The person of ordinary skill in the art of electronic materials is familiar with the use of thermosetting compositions like those described herein in the production of a variety of products such as prepregs, resin films, resin-coated copper, laminates, and printed circuit boards.

One component of the thermosetting compositions of the disclosure is an aromatic epoxy resin component, present in a total amount in the range of 5-25 wt %. As used herein, an aromatic epoxy resin component is made up of one or more aromatic epoxy resin subcomponents that bear at least 2 epoxy groups per molecule, on a number average basis. They aromatic epoxy resin component is desirably liquid at 25° C. The present inventors have noted that the aromatic epoxy resin component can provide a variety of advantageous properties to the material, including suitably fast curing (together with other components of the composition), flame retardance and self-extinguishing character, thermal stability, chemical resistance and adhesion, e.g., to glass and metal materials.

The person of ordinary skill in the art can, in view of the description herein, can determine an appropriate amount of the aromatic epoxy resin component from within the range of 5-25 wt %. For example, in various embodiments of the thermosetting compositions as otherwise described herein, the aromatic epoxy resin component is present in an amount in the range of 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %.

Desirably, the aromatic epoxy resin component has a high aromatic fraction. This can help to provide high thermal stability and flame retardance, especially when the aromatic epoxy resin component is substantially halogen-free (e.g., no more than 1 wt % halogen, or no more than 0.5 wt % halogen), which is highly desirable. As used herein, an “aromatic carbon fraction” of a material is the percentage of carbon atoms in the material that are aromatic. For example, anthracene has an aromatic carbon fraction of 100%, while tetramethylbenzene has an aromatic carbon fraction of 60%. In various embodiments as otherwise described herein, the aromatic epoxy resin component has an aromatic carbon fraction of at least 60%, e.g., at least 65%. In various embodiments as otherwise described herein, the aromatic epoxy resin component has an aromatic carbon fraction of at least 70%, e.g., at least 75%. However, it is desirable for some non-aromatic character to be present, in order to provide for a degree of molecular flexibility, and to account for the epoxy carbons of the material. Accordingly, in various embodiments, the aromatic epoxy resin component has an aromatic carbon fraction in the range of 60-85%, e.g., 65-85%, or 60-82%, or 65-82%, or 60-80%, or 65-80%, or 60-75%, or 65-75%. In various embodiments, the aromatic epoxy resin component has an aromatic carbon fraction in the range of 70-85%, e.g., 75-85%, or 70-82%, or 75-82%, or 70-80%, or 75-80%.

The present inventors note that a variety of aromatic epoxy resins can be useful in the compositions of the disclosure. For example, in various embodiments as otherwise described herein, the aromatic epoxy resin component comprises one or more of a novolac type epoxy resin (e.g., a biphenyl novolac epoxy resin, a phenol novolac epoxy resin, a cresol novolac epoxy resin), a bisphenol epoxy resin (e.g., a bisphenol A epoxy resins, a bisphenol F epoxy resins, and a bisphenol S epoxy resin), a biphenyl epoxy resin, a xylylene epoxy resin, an aryl alkylene epoxy resin (e.g., a phenol aralkyl epoxy resins, a biphenyl aralkyl epoxy resin, biphenyl novolac epoxy resins, a biphenyl dimethylene epoxy resin, a trisphenol methane novolac epoxy resin, and a tetramethyl biphenyl epoxy resin); and a naphthalene epoxy resin.

The person of ordinary skill in the art will appreciate that in a phenolic epoxy resin (such as a bisphenol epoxy resin or a novolac epoxy resin) as described herein there may be some minor degree of phenolic character remaining (e.g., no more than 5% of phenolic oxygens unsubstituted with epoxy-bearing substituents) with the resin still being represented by the generic formulas provided here.

Especially suitable are resins of the NC-3000 series and NC-2000 series from Nippon Kayaku; KES-7370, available from Kolon Industries, and materials of the PNE series (e.g., PNE-177), available from Chang Chun Petrochemical.

In various desirable embodiments, the aromatic epoxy resin component includes at least one biphenyl novolac epoxy resin (e.g., a biphenyl aralkyl epoxy resin). In various embodiments, the at least one biphenyl novolac epoxy resin comprises (or is) a resin having the generic structure

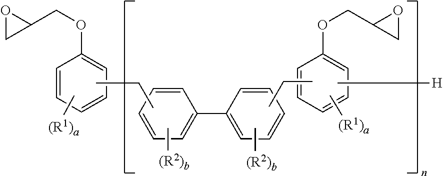

wherein each R₁ and R₂ is independently alkyl having 1 to 4 carbon atoms; a is in the range of 0 to 3, b is in the range of 0 to 4; and n has a number-average value in the range of 1-6 (e.g., 2-6, or 3-6, or 1-5, or 2-5, or 3-5). In various embodiments, each R¹ and R² is independently methyl or ethyl and each a and b is independently 0, 1 or 2. In various embodiments, each a and b is 0. In various embodiments, the at least one biphenyl novolac epoxy resin comprises (or is) a resin having the generic structure

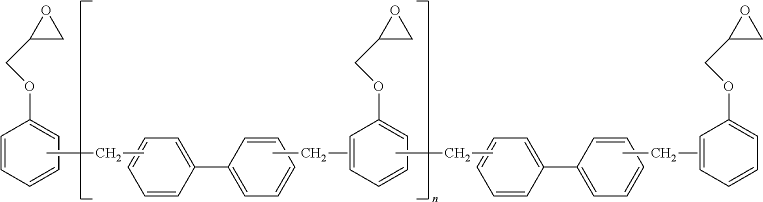

wherein n has a number-average value in the range of 1-6 (e.g., 2-6, or 3-6, or 1-5, or 2-5. or 3-5). The present inventors have noted that such materials can enhance the thermal stability, flame retardance and self-extinguishing characteristics of the materials made from the thermosetting composition, while providing good reactivity and network formation.

The at least one biphenyl novolac epoxy can be present in a variety of amounts in the thermosetting composition, for example, in the range of 5-25 wt %, e.g., in the range 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %.

In various desirable embodiments, the aromatic epoxy resin component includes at least one phenol novolac epoxy resin. In various embodiments, the at least one phenol novolac epoxy resin has the generic structure

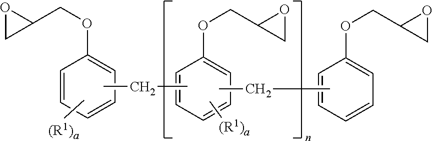

in which each R₁ is independently alkyl having 1 to 4 carbon atoms; a is in the range of 0 to 3, and n has a number-average value in the range of 1-6 (e.g., 2-6, or 3-6, or 1-5, or 2-5, or 3-5). In various embodiments, each R¹ is independently methyl or ethyl and each a is independently 0, 1 or 2. In various embodiments, each a is 0. One example of such a resin (in which each a is 0) is available from Chung Chen Petrochemicals under the designation PNE-177, and has an epoxy equivalent weight (g/eq) of 172-182 and a viscosity of 20000-80000 cps at 52° C. when neat; materials with added solvent (e.g., acetone, MEK or xylene) are also available, and have lower viscosity. The present inventors note that such materials can enhance adhesion and chemical resistance of materials made from the thermosetting composition.

The at least one phenol novolac epoxy can be present in a variety of amounts in the thermosetting composition, e.g., 5-25 wt %, or 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %. However, the present inventors have noted that at higher levels, flame resistance can be reduced. Accordingly, in various desirable embodiments, the phenol novolac epoxy is present in an amount in the range of 1-10 wt %, e.g., 1-7 wt %, or 1-5 wt %, or 2-10 wt %, or 2-7 wt %, or 2-5 wt %, or 3-10 wt %, or 3-7 wt %, or 3-5 wt %.

In various desirable embodiments, the aromatic epoxy resin component includes both a biphenyl novolac epoxy resin and a phenol novolac epoxy resin. For example, in various such embodiments, a weight ratio of biphenyl novolac epoxy to phenol novolac epoxy is in the range of 1:1 to 15:1, e.g., 2:1 to 10:1, or 2:1 to 5:1, or 2:1 to 3:1. The present inventors note that use of such a ratio can provide a good balance of adhesion and chemical resistance with flame resistance and heat stability.

The aromatic epoxy resin component can be provided with a variety of epoxy equivalent values, for example, in the range of 150 g/eq to 350 g/eq.

The present inventors note that non-aromatic epoxy resins can be present in some embodiments of the thermosetting compositions as generally described herein. However, it is noted that such is not necessary, and inclusion of such materials in high amounts can be detrimental to various desirable properties of the materials made using the thermosetting compositions of the disclosure. Accordingly, in various embodiments as otherwise described herein, an amount of any non-aromatic epoxy resins is no more than 10 wt %, e.g., no more than 5 wt %, or no more than 2 wt %, or no more than 1 wt %,

As described above, the thermosetting compositions of the disclosure also include a poly(styrene-co-maleic anhydride) component. The present inventors have noted that such materials can help to enhance heat resistance and dielectric properties (e.g., Dk and Df) in the materials made with the thermosetting compositions of the disclosure.

The person of ordinary skill in the art can, in view of the description herein, can determine an appropriate amount of the poly(styrene-co-maleic anhydride) component from within the range of 8-30 wt %. For example, in various embodiments, the poly(styrene-co-maleic anhydride) component is present in an amount in the range of 8-25 wt %, or 8-22 wt %, or 8-20 wt %, or 8-18 wt %, or 10-30 wt %, or 10-25 wt %, or 10-22 wt %, or 10-20 wt %, or 10-18 wt %. In various embodiments, the poly(styrene-co-maleic anhydride) component is present in an amount in the range of 12-30 wt %, e.g., 12-25 wt %, or 12-22 wt %, or 12-20 wt %, or 12-18 wt %, or 14-30 wt %, or 14-25 wt %, or 14-22 wt %, or 14-20 wt %, or 14-18 wt %.

The person of ordinary skill in the art will appreciate that a variety of poly(styrene-co-maleic anhydride) products are available, with a varying molar ratio of styrene to maleic anhydride residues, e.g., 8:1, 6:1, 4:1 and 3:1. Desirably, the poly(styrene-co-maleic anhydride) component has no more than 5 wt % or residues that are not styrene residues or maleic anhydride residues (i.e., or acid analogs thereof), e.g., no more than 2 wt %, or no more than 1 wt %.

The present inventors have noted that the ratio of styrene to maleic anhydride residues of poly(styrene-co-maleic anhydride) component can be selected to provide a desirable set of properties to the material made from the thermosetting composition. For example, relatively more maleic anhydride residues can favor better electrical properties, and relatively more styrene residues can provide increased glass transition temperature. In various examples, the poly(styrene-co-maleic anhydride) component has a ratio of styrene to maleic anhydride residues in the range of 2:1-6:1, e.g., 2:1-5:1, or 2:1-4:1, or 2.5:1-6:1, or 2.5:1-5:1, or 2.5:1-4:1, or 3:1-6:1, or 3:1-5:1, or 3:1-4:1.

The present inventors note that a ratio in the range of 3:1-4:1 can provide an especially desirable balance of properties. This can be provided by a poly(styrene-co-maleic anhydride) component that comprises (or is) a blend of a first poly(styrene-co-maleic anhydride) polymer having a ratio of styrene to maleic anhydride residues in the range of 2.8:1-3.2:1, and a second poly(styrene-co-maleic anhydride) polymer having a ratio of styrene to maleic anhydride residues in the range of 3.8:1-4.2:1. XIRAN® EF30 and XIRAN® EF40, available from Polyscope, are examples of 3:1 and 4:1 ratio products that are suitable for use.

As described above, the thermosetting compositions of the disclosure also include a maleimide-bearing oligomer component. As used herein, a maleimide-bearing oligomer component having at least 3 maleimides per molecule, on a number average, and a softening point of no more than 100° C. as measured in a ring-and-ball softening test (e.g., according to ISO 18280 or JIS K7234). The present inventors have noted that use of such materials can enhance toughness and thermal reliability and reduce warpage in materials made with the thermosetting compositions. Moreover, they can help to improve solubility of components within the thermosetting composition overall.

The person of ordinary skill in the art can, in view of the description herein, can determine an appropriate amount of the maleimide-bearing oligomer component, from within the range 2-10 wt %, for use in the thermosetting composition. For example, in various embodiments as otherwise described herein, the maleimide-bearing oligomer component is present in an amount in the range of 2-9 wt %, or 2-7 wt %, or 3-10 wt %, or 3-9 wt %, or 3-7 wt %, or 5-10 wt %, or 5-9 wt %, or 5-7 wt %.

In various embodiments, the maleimide-bearing oligomer component has at least 4 maleimides per molecule, e.g., at least 5, or at least 6, on number average. In various embodiments, the maleimide-bearing oligomer component has in the range of 3-10 maleimides per molecule, e.g., in the range of 4-10, or 5-10, or 6-10, or 3-9, or 4-9, or 5-9, or 6-9, on number average. In various embodiments, the maleimide-bearing oligomer component has in the range of 3-8 maleimides per molecule, e.g., in the range of 4-8, or 5-8, or 6-8, or 3-7, or 4-7, or 5-7, on number average.

The maleimide-bearing oligomer desirably has a relatively high aromatic carbon content, in order to improve thermal stability and various other properties. In various embodiments as otherwise described herein, the maleimide-bearing oligomer component an aromatic carbon fraction of at least 80%, e.g., at least 84%, or at least 88%.

In various embodiments, the maleimide-bearing component has a softening point of no more than 95° C., e.g., no more than 90° C., as measured in a ring-and-ball softening test (e.g., according to ISO 18280 or JIS K7234). In various embodiments, the maleimide-bearing component has a softening point of in the range of 70-100° C., e.g., 75-100° C., or 80-100° C., or 70-95° C., or 75-95° C., or 80-95° C., or 70-90° C., or 75-90° C., or 80-90° C., or 70-85° C., or 75-85° C., or 80-85° C., as measured in a ring-and-ball softening test (e.g., according to ISO 18280 or JIS K7234). In various embodiments, the maleimide-bearing oligomer component has a softening point in the range of 80-95° C., or 70-90° C., or 75-90° C., or 80-90° C., or 70-85° C., or 75-85° C., or 80-85° C., as measured in a ring-and-ball softening test (e.g., according to ISO 18280 or JIS K7234).

A wide variety of maleimide-bearing oligomers can be suitable for use in the thermosetting compositions of the disclosure. In various embodiments as otherwise described herein, the maleimide-bearing oligomer has the general structure.

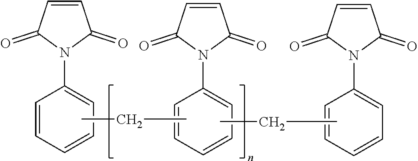

in which n is selected to give a desirable number of maleimide residues per molecule, as otherwise described.

As described above, the thermosetting composition also includes a benzoxazine/maleimide component, that is a bis(benzoxazine) subcomponent and a bis(maleimide) subcomponent, and/or a reaction product thereof, present in an amount in the range of 2-20 wt %. The present inventors have found that use of such a component, be it as individual components or a prepolymeric form as a reaction product thereof, can enhance flame retardancy, enhance electrical properties such as Dk and Df and provide good dimensional stability of materials made from the thermosetting composition.

As used herein, a bis(benzoxazine) subcomponent is a monomer subcomponent that bears two reactive benzoxazine moieties, which themselves may be N-substituted (e.g., with alkyl or phenyl groups). Similarly, a bis(maleimide) subcomponent is a monomer subcomponent that bears two reactive maleimide moieties.

The person of ordinary skill in the art can, based on the disclosure herein, provide a suitable amount of the benzoxazine/maleimide component from within the range of 2-20 wt %. For example, in various embodiments as otherwise described herein, the benzoxazine/maleimide component is present in an amount in the range of 2-17 wt %, or 2-15 wt %, or 2-12 wt %, or 2-9 wt %, or 4-20 wt %, or 4-17 wt %, or 4-15 wt %, or 4-12 wt %, or 4-9 wt %, or 6-20 wt %, or 6-17 wt %, or 6-15 wt %, or 6-12 wt %, or 6-9 wt %.

A variety of bis(benzoxazine) subcomponents are suitable for use in the benzoxazine/maleimide component. For example, in various embodiments, the bis(benzoxazine) subcomponent comprises (or is) one or more of the following:

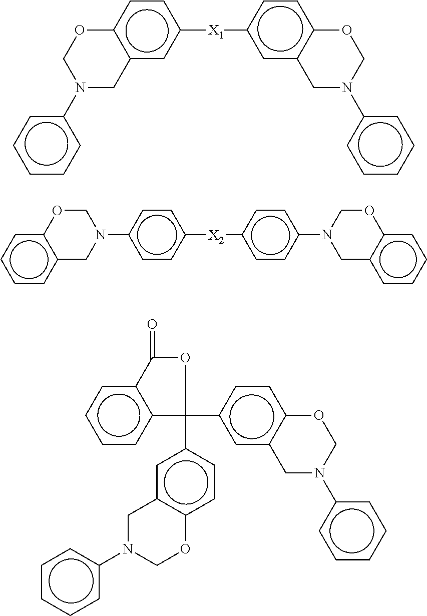

in which each of X₁ and X₂ is independently an arylene (e.g., phenylene, biphenylene, naphthylene); C₁-C₃ alkylene (desirably substituted at the same carbon, such as —C(CH₃)₂—CH(CH₃)—, —CH₂—), or S(O)₀₋₂. For example, in various embodiments, the bis(benzoxazine) subcomponent comprises (or is) one or more of the following:

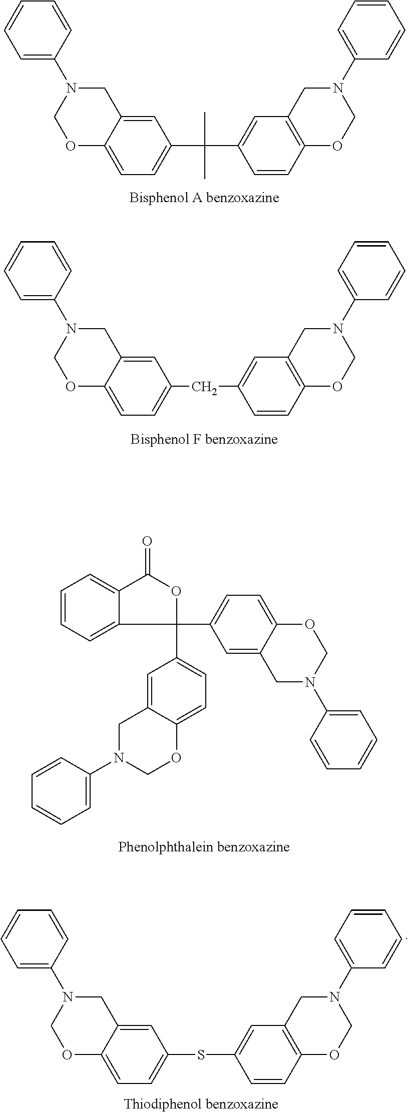 [SMILES: CC(C)(c1ccc2c(c1)CN(c1ccccc1)CO2)c1ccc2c(c1)CN(c1ccccc1)CO2 ; c1ccc(N2COc3ccc(Cc4ccc5c(c4)CN(c4ccccc4)CO5)cc3C2)cc1 ; O=C1OC(c2ccc3c(c2)CN(c2ccccc2)CO3)(c2ccc3c(c2)CN(c2ccccc2)CO3)c2ccccc21 ; c1ccc(N2COc3ccc(Sc4ccc5c(c4)CN(c4ccccc4)CO5)cc3C2)cc1]

For example, in various desirable embodiments, the bis(benzoxazine) subcomponent comprises (or is) bisphenol F benzoxazine.

A variety of bis(maleimide) subcomponents are suitable for use in the benzoxazine/maleimide component. For example, in various embodiments, the bis(maleimide) subcomponent comprises (or is) one or more of 4,4′-bismaleimidodiphenylmethane, bis(3-ethyl-5-methyl-4-maleimidophenyl)methane, 2,2-bis[4-(4-maleimidophenoxy)phenyl]propane, m-phenylenebismaleimide, 4-methyl-1,3-phenylene bismaleimide and N,N′-1,4-phenylenedimaleimide. For example, in various embodiments, the bis(maleimide) subcomponent comprises (or is) 4,4′-bismaleimidodiphenylmethane.

In various embodiments as otherwise described herein, the benzoxazine/maleimide component is provided as a prepolymer of the bis(benzoxazine) subcomponent and the bismaleimide subcomponent (e.g., a bisphenol F benzoxazine/4,4′-bismaleimidodiphenylmethane prepolymer). The prepolymer can be further derivatized, e.g., to reduce OH content. A suitable prepolymer material is LZ-8298, available from Huntsman.

The ratio of the bis(benzoxazine) subcomponent to the bis(maleimide) subcomponent can vary. Each of benzoxazine and maleimide can react with itself and with other components of the thermosetting composition, and so there need not be molar parity between the subcomponents. In various embodiments, a molar ratio of the bis(benzoxazine) subcomponent to the bis(maleimide) subcomponent is in the range of 2:1 to 1:2, e.g., in the range of 1.5:1 to 1:2, or 1.25:1 to 1:2, or 1:1 to 1:2, or 2:1 to 1:1.5, or 1.5:1 to 1:1.5, or 1.25:1 to 1:1.5, or 1:1 to 1:1.5, or 2:1 to 1:1.25, or 1.5:1 to 1:1.25, or 1.25:1 to 1:1.25, or 1:1 to 1:1.25, or 2:1 to 1:1, or 1.5:1 to 1:1, or 1.25:1 to 1:1. In other embodiments, the molar ratio of the bis(benzoxazine) subcomponent to the bis(maleimide) subcomponent is in the range of 9:1 to 2:1, e.g., 7:1 to 2:1, or 5:1 to 2:1, or 4:1 to 2:1. In other embodiments, the molar ratio of the bis(benzoxazine) subcomponent to the bis(maleimide) subcomponent is in the range of 1:9 to 1:2, e.g., 1:7 to 1:2, or 1:5 to 1:2, or 1:4 to 1:2.

The benzoxazine/maleimide component desirably has a high aromatic content. For example, in various embodiments, the benzoxazine/maleimide component has an aromatic carbon content of at least 60%, e.g., at least 65%, or at least 67%, or at least 70%. Of course, the person of ordinary skill in the art will appreciate that the oxazine carbons will not be aromatic, and that residues in a prepolymer that are derived from maleimide likewise may not be aromatic.

As described above, the thermosetting compositions of the disclosure also include an aromatic primary diamine component. The present inventors have noted that the use of an aromatic primary diamine can increase the crosslinking density of the system and thus improve a number of properties.

The person of ordinary skill in the art can, based on the present disclosure, determine an appropriate amount of the aromatic primary diamine component within the range of 0.05-2 wt %. For example, in various embodiments, the aromatic primary diamine component is present in an amount of 0.05-1.5 wt %, or 0.05-1 wt %, or 0.05-0.7 wt %, or 0.1-2 wt %, or 0.1-1.5 wt %, or 0.1-1 wt %, or 0.1-0.7 wt %.

A variety of aromatic primary diamines can be suitable for use in the thermosetting compositions of the disclosure. In various embodiments, the aromatic primary diamine component comprises (or is) 4,4′-(diaminodiphenyl)sulfone, 4,4′-diaminodiphenyl(ether), or 4,4′-diaminodiphenyl(methane). In various embodiments, the aromatic primary diamine component comprises (or is) 4,4′-(diaminodiphenyl)sulfone.

The aromatic primary diamine component desirably has a high aromatic content. For example, in various embodiments, the aromatic primary diamine component has an aromatic carbon content of at least 90%, e.g., at least 95% or at least 98% or at least 99%.

The thermosetting composition also includes microparticulate silica, in an amount in the range of 15-50 wt %. As used herein, a microparticulate silica is a particulate material that is at least 95 wt % SiO₂ and has a d₅₀ particle size in the range of 0.1-100 microns. In various embodiments, the microparticulate silica has a d₅₀ particle size in the range of 0.5-10 microns, e.g., 0.5-7 microns, or 0.5-5 microns, or 1-10 microns, or 1-7 microns, or 1-5 microns. In various embodiments, the microparticulate silica has a d₉₀ particle size in the range of 1-20 microns, e.g., 1-14 microns, or 1-8 microns, or 3-20 microns, or 3-14 microns, or 3-8 microns. In various embodiments, the microparticulate silica has a d₁₀ particle size in the range of 0.1-5 microns, e.g., 0.1-3 microns, or 0.1-2 microns, or 0.5-5 microns, or 0.5-3 microns, or 0.5-2 microns. In various embodiments, the microparticulate silica has at least 99 wt % SiO₂, e.g., at least 99.5 wt % SiO₂.

The microparticulate silica is desirably substantially spherical. The person of ordinary skill in the art can use microscopy to confirm sphericity.

Suitable microparticulate silicas are available from a variety of vendors, including DQ-1028L, available from Novoray; SS-15V, available from Sibelco; and FB-3SDC and FB-3SDX, available from Denka Co. Ltd.

The amount of microparticulate silica can vary. For example, in various embodiments, the microparticulate silica is present in an amount in the range of 15-45 wt %, or 15-40 wt %, or 15-35 wt %. In various particular embodiments, the microparticulate silica is present in an amount in the range of 20-50 wt %, e.g., 20-45 wt %, or 20-40 wt %, or 20-35 wt %. In various particular embodiments, the microparticulate silica is present in an amount in the range of 20-50 wt %, e.g., 25-45 wt %, or 25-40 wt %, or 25-35 wt %.

The thermosetting composition also includes an organic halogen-free fire retardant component, present in an amount of 3-25 wt %. In various embodiments, the organic halogen-free fire retardant comprises phosphorus.

Particular fire retardants described in U.S. Pat. Nos. 8,536,256, 9,012,546, 9,522,927 and 9,562,063 are suitable for use in the presently-described thermosetting compositions. Accordingly, these patents are hereby incorporated herein by reference in their entirety, and their text is copied below; the present disclosure contemplates the use of any fire retardant as generically or specifically described in any of these patents as part of the organic halogen-free fire retardant component of the thermosetting composition of the disclosure, alone or in combination. For example, in various embodiments, the organic halogen-free fire retardant component includes (or is) 6H-Dibenz[c,e][1,2]oxaphosphorin, 6,6′-(1,4-ethanediyl)bis-, 6,6′-dioxide; 6H-Dibenz[c,e][1,2]oxaphosphorin, 6,6′-(1,4-butanediyl)bis-, 6,6′-dioxide; or 6H-Dibenz[c,e][1,2]oxaphosphorin, 6,6′-(p-xylenediyl)bis-, 6,6′-dioxide; or any combination thereof. In various embodiments, the fire retardant component includes (or is) is 6H-Dibenz[c,e][1,2]oxaphosphorin, 6,6′-(1,4-ethanediyl)bis-, 6,6′-dioxide. In various embodiments, the fire retardant component includes (or is) a compound having the structure: having the following structure:

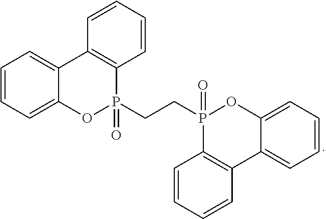 [SMILES: O=P1(CCP2(=O)Oc3ccccc3-c3ccccc32)Oc2ccccc2-c2ccccc21]

In various embodiments, the fire retardant component includes (or is) composition comprising the high melting point isomer of Formula IIa:

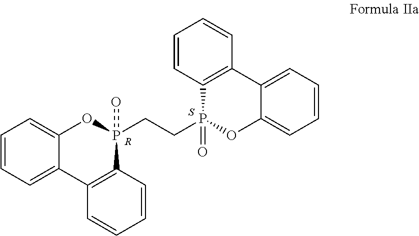

and the low melting point isomers of Formula IIb and IIc having the Formulas:

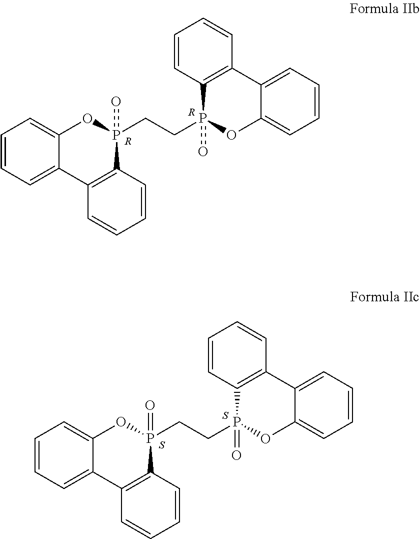

wherein said composition has an Isomer Ratio of greater than about 0.5 utilizing the 31P NMR method and wherein said Isomer Ratio=Aₕ/(Aₕ+Aᵢ), wherein Aₕ: area of high melting point isomer peak and Aᵢ: area of low melting point isomers peak.

Another especially suitable phosphorus-based fire retardant is a diaryl phosphine oxide-based fire retardant. Accordingly, in various embodiments as otherwise described herein, the organic halogen-free fire retardant component comprises (or is) a diaryl phosphine oxide-based fire retardant, for example, a diphenyl phosphine oxide-based fire retardant. In various embodiments, the organic halogen-free fire retardant component comprises (or is) a compound of the structural formula

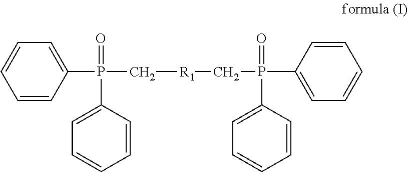

wherein R₁ is selected from the group consisting of a covalent bond, —CH₂—,

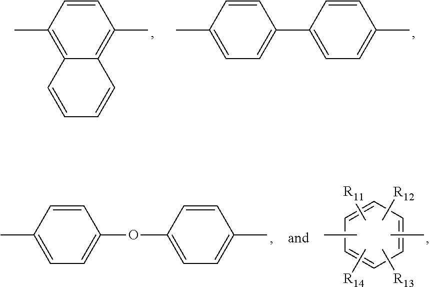

in which R₁₁, R₁₂, R₁₃, and R₁₄ are independently H, alkyl, or

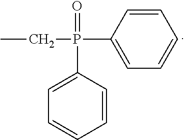 [SMILES: CCP(=O)(c1ccccc1)c1ccccc1]

For example, in various embodiments, the halogen-free fire retardant comprises (or is) xylylene diphenylphosphine oxide represented by the following formula:

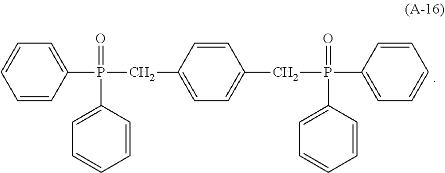 [SMILES: O=P(Cc1ccc(CP(=O)(c2ccccc2)c2ccccc2)cc1)(c1ccccc1)c1ccccc1]

But the person of ordinary skill in the art will appreciate that other halogen-free fire retardants can be used, in addition to or even instead of those described above. Examples include phosphorus-containing fire retardant, such as ammonium polyphosphate, hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201, and PX-202), phosphazene (such as commercially available SPB-100, SPH-100, and SPV-100), melamine polyphosphate, DOPO (9,10-dihydro-9-oxa-10-phosphaphenanthrene-10-oxide) and its derivatives or resins, DPPO (diphenylphosphine oxide) and its derivatives or resins, aluminum phosphinate (e.g., commercially available OP-930 and OP-935).

The organic halogen-free fire retardant component can be provided in the thermosetting composition in a variety of amounts within the broader range of 3-25 wt %. For example, in various embodiments, the organic halogen-free fire retardant component is present in an amount of 3-20 wt %, e.g., 3-15 wt %. In various embodiments, the organic halogen-free fire retardant component is present in an amount of 4-25 wt %, e.g., 4-20 wt %, or 4-15 wt %. In various embodiments, the organic halogen-free fire retardant component is present in an amount of 5-25 wt %, e.g., 5-20 wt %, or 5-15 wt %.

As noted above, the thermosetting composition also includes an effective amount of one or more catalysts. The one or more catalysts are, together, effective to cure the thermosetting composition. The person of ordinary skill in the art is aware of a variety of catalysts effective to cure the epoxy systems described here, and can select one or more of them, in desirable amount(s) to provide initial polymerization of the thermosetting composition to a B-staged composition, and to further polymerize the B-staged composition to a substantially-polymerized composition, e.g., in laminate form.

For example, in various embodiments, the one or more catalysts includes a tertiary amine catalyst, e.g., an N-substituted imidazole catalyst such as 2-phenylimidazole, 2-methylimidazole, or 2-ethylimidazole. Tertiary amines are well known as epoxy hardeners, and the person of ordinary skill in the art can select from these and others to provide a desired catalytic activity.

In various embodiments, the one or more catalysts includes a phase transfer catalyst (e.g., together with a tertiary amine, or not). Examples include salts of quaternary phosphonium or a quaternary ammonium, e.g., a tetraalkylphosphonium salt (such as tetrabutyl acetate); a tetraalkylammonium salt or a benzyltrialkylammonium salt. Phase transfer catalysts are also well-known in the curing of epoxy systems, and the person of ordinary skill in the art can select from these and others to provide a desired catalytic activity.

The person of ordinary skill in the art can determine an effective amount of the one or more catalysts. For example, in various embodiments, the effective amount of the one or more catalysts is in the range of 0.005-1 wt %, e.g., 0.005-0.5 wt % or 0.005-0.2 wt %, or 0.005-0.1 wt %, or 0.01-1 wt %, or 0.01-0.5 wt %, or 0.01-0.2 wt %, or 0.01-0.1 wt %.

The one or catalysts can be provided in some embodiments with a carrier; the person of ordinary skill in the art will appreciate that the mass of a catalyst component is calculated as the mass of the catalysts compound(s) themselves, omitting the mass of any carriers.

Additional components than those outlined above can be present in some embodiments. For example, in various embodiments, the thermosetting composition can also include a phosphorus modified phenolic resin, in an amount in the range of up to 15 wt %, e.g., up to 10 wt %, or up to 8 wt %. The use of a phosphorus-modified phenolic resin can help further improve fire performance, while providing good mechanical properties. One such example has the structure

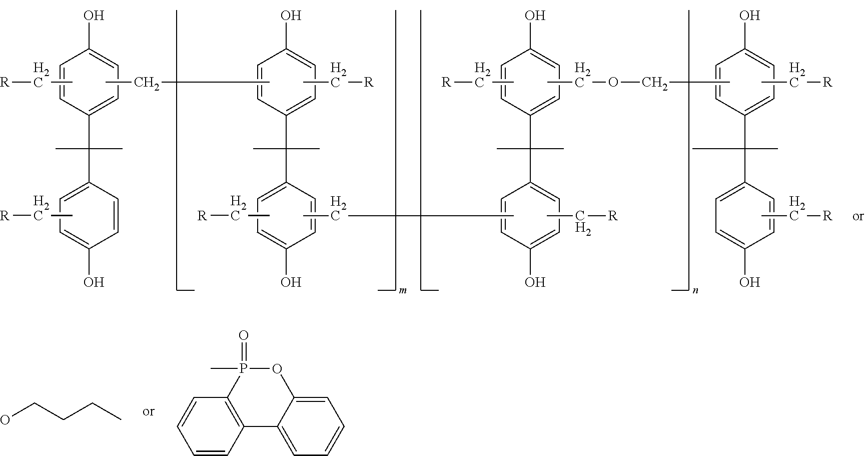

in which each R is independently one of the structures at the right of the diagram and m is, e.g., in the range of 1-100. One such material is available under the designation KIH-G800 from Kolon Industries.

Moreover, in various embodiments, the thermosetting composition can also include a silane coupling agent, e.g., to provide bonding to the microparticulate silica filler and/or to a glass material used in making a prepreg or laminate. The person of ordinary skill in the art is familiar with silane coupling agents, and can select a suitable one based on the description herein. For example, the silane coupling agent can in some embodiments be selected from one or more of epoxy-functional silanes and amine-functional silanes. In various embodiments, the epoxy-functional or amine-functional silane is a C₁-C₃ alkoxy silane, e.g., a methoxysilane or an ethoxysilane, such as a trimethoxysilane or a triethoxysilane. In various embodiments, the epoxy-functional or amine-functional silane comprises (or is) an epoxy-functional silane such as (3-glycidyloxypropyl)trimethoxysilane or (3-glycidyloxypropyl)triethoxysilane. In various embodiments, the epoxy-functional or amine-functional silane comprises (or is) an amino-functional silane, such as (3-aminopropyl)trimethoxysilane or (3-aminopropyl)triethoxysilane.

The silane coupling agent can be present in an amount, e.g., up to 2 wt %, e.g., up to 1 wt %. In various embodiments, the silane coupling agent is present in an amount in the range of 0.1-2 wt %, e.g., in the range of 0.1-1.5 wt %, or 0.1-1 wt %, or 0.2-2 wt %, or 0.2-1.5 wt %, or 0.2-1 wt %.

The amounts described herein for components of the thermosetting composition are on a dry solids basis, i.e., with 100 wt % being the total of the non-volatile (i.e., boiling point less than 200° C. at atmospheric pressure) components of the composition. In various embodiments, the thermosetting composition is provided in substantially non-volatile form, i.e., without a substantial amount of a solvent. The present inventors have noted that thermosetting compositions as described here can in many embodiments be provided with desirable viscosities without the use of large amounts of solvent. Accordingly, in various embodiments, the thermosetting compositions as described herein can be provided with no more than 10 wt % material having a boiling point at atmospheric pressure of less than 200° C., e.g., no more than 5 wt %, or no more than 3 wt %, or no more than 1 wt %, all calculated with the non-volatile content being 100 wt % as described above.

However, the present inventors note that a solvent can be useful to provide the material with a lower viscosity for processing, especially in the impregnation of a glass or polymer fabric for making a prepreg. Accordingly, in various embodiments, the thermosetting composition also includes a solvent having a boiling point at atmospheric pressure of less than 200° C. The person of ordinary skill in the art will appreciate that a variety of solvents could be used, alone or in combination, and will determine an appropriate solvent in which to suspend the various components of the composition. Potential examples include y-butyrolactone, cyclohexanone, butanone, methyl isobutyl ketone, N,N-dimethylformamide, propylene glycol monomethyl ether, N,N-dimethylacetamide, ethylene glycol monomethyl ether, methoxy ethyl acetate, ethoxy ethyl acetate, propoxy ethyl acetate, diisobutyl ketone (DIBK), N-methyl-pyrrolidone, xylene, ethyl acetate, toluene, trichloroethane, dibutyl ether, methyl ethyl ketone, and acetone. Similarly, the person of ordinary skill in the art will appreciate that the amount of solvent can be varied to provide a desired viscosity; in various embodiments, the amount of solvent is up to 60 wt %, e.g., in the range of 20-60 wt %, in excess of the non-volatile components of the thermosetting composition (i.e., taken together as 100 wt %).

Another aspect of the disclosure is a cured product of a thermosetting composition as described herein. As the person of ordinary skill in the art will appreciate, the cured product can in some embodiments be only partially-cured, e.g., to an extent to form a solid form, such that it is handleable but can be more fully cured by further processing. This partial curing can be to a so-called “B-stage,” or to a lesser or further extent. In other embodiments, the cured product can be substantially fully cured, so that it is substantially stable to further processing. A variety of curing conditions may be used, but typically curing temperatures are in the range of 100-250° C., for a time sufficient to arrive at a desired degree of cure.

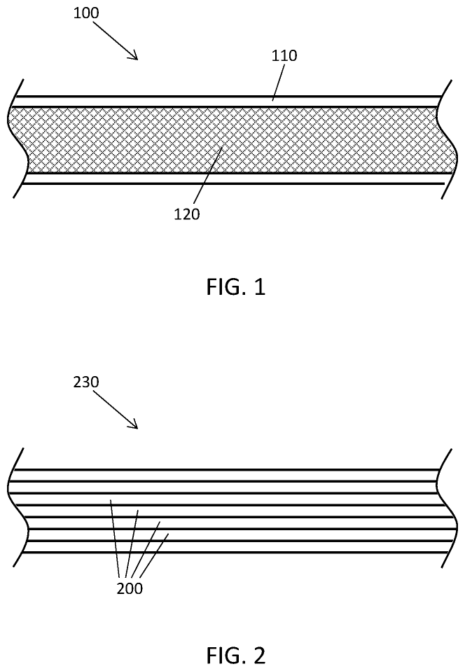

Another aspect of the disclosure is a prepreg comprising a mesh substrate at least partially embedded in a cured product of the disclosure, desirably a partially-cured product that can be further cured by further heating at a later time. One embodiment is shown in schematic cross-sectional view in FIG. 1. Here, prepreg 100 comprises mesh substrate 110, embedded in a cured product of the disclosure 120.

The person of ordinary skill in the art can use a variety of mesh substrates. For example, in various embodiments, the mesh substrate is a fabric (woven or non-woven), e.g., made from glass fiber, carbon fiber, or various polymer fibers such as aramid fiber such as the material available under the trade name KEVLAR. In particular desirable embodiments, the substrate is a borosilicate glass fabric. In some such embodiments, the glass is formed, on an oxide basis, of SiO₂ (50-80 wt %), B₂O₃ (5-25 wt %), with optional components including without limitation CaO (up to 30 wt %) Al₂O₃ (up to 20 wt %) and MgO (up to 5 wt %). Examples of suitable glass fabrics include electronic grade E-glass fabric, NE-glass fabric, D-glass fabric, and S-glass fabric. In various embodiments, the mesh substrate is substantially embedded in the cured product. As the person of ordinary skill in the art will appreciate, prepregs can be made of a variety of overall thicknesses, but in some embodiments, the prepreg is in the range of 10-300 microns in thickness, e.g., 10-200 microns, or 10-150 microns, or 10-100 microns. In some embodiments, the prepreg is in the range of 25-300 microns in thickness, e.g., 25-200 microns, or 25-150 microns, or 25-100 microns. In some embodiments, the prepreg is in the range of 50-300 microns in thickness, e.g., 50-200 microns, or 50-150 microns. The prepreg desirably includes at least 30 wt % of the cured product of the disclosure, e.g., at least 50 wt %.

The person of ordinary skill in the art is familiar with methods for making prepregs, and will adapt such methods for use with the thermosetting composition of the disclosure. The thermosetting composition can be contacted with the mesh substrate, dried as necessary to remove any volatiles, and cured by heating to cause the thermosetting composition to at least partially cure it to provide the prepreg.

Another aspect of the disclosure is a laminate of a plurality of prepregs of the present disclosure. One example is shown in schematic perspective view in FIG. 2. Here, laminate 230 includes a laminate of a plurality of prepregs 200. The laminate can be made by heat-pressing a plurality of prepregs as described herein to cause softening and further curing of partially-cured material of the prepregs to fuse them together into a laminate structure. Heat pressing conditions can vary, but can generally be in the range of 150-250° C. and 1-10 MPa. The further curing in many embodiments can substantially fully cure the material. As used herein, substantial full curing can be determined using a delta Tg measurement, in which a material is run to 250° C. in a differential scanning calorimeter and a first Tg determined. The sample is then cooled to room temperature, and a Tg measurement up to 250° C. is repeated to provide a second Tg. If the difference between the first Tg and the second Tg is no more than 10° C., the material is said to be substantially fully cured. Here, too, the person of ordinary skill in the art is familiar with techniques for forming laminates from prepregs, and will adapt them for use with the prepregs of the disclosure.

The laminates of the disclosure can include one or more layers of metal, such as copper. The one or more layers of metal can be disposed, e.g., on one or both major surfaces of the laminate, and/or laminated in between layers of prepregs. Each layer of metal can be substantially uniform, or can be provided in the form of circuits, e.g., by etching. As the person of ordinary skill in the art will appreciate, a circuit board laminate can be built in a plurality of steps, e.g., by providing a first laminate with metal on one or both surfaces thereof, then forming a circuit out of such metal, then further laminating the so-processed first laminate with additional layers of prepreg and metal to form a multilayer laminate. Thicknesses can vary; in various embodiments, the areal-averaged thickness of a metal layer (e.g., a copper layer) is in the range of 10-500 microns, e.g. 10-250 microns, or 10-100 microns, or 20-500 microns, or 20-250 microns, or 20-100 microns.

The present inventors have found that the materials described herein have a variety of desirable properties, including low Df and Dk values, good peel strength, and high glass transition temperature. For example, in various embodiments, the laminate has a Dk value in the range of 3.5 to 4.5, e.g., 3.65-4.5, or 3.8-4.5, or 3.65-4.35, as measured by IPC-TM-650 2.5.5.9. In various embodiments, the laminate has a Df value in the range of 0.003 to 0.009, e.g., 0.004 to 0.009, or 0.005-0.009 as measured by IPC-TM-650 2.5.5.9. In various embodiments, the laminate has a peel strength (1/2 oz Very Low Profile Cu foil) of at least 2.5 lb/in as measured by IPC-TM-650 2.4.8 (e.g., at least 3 lb/in, or at least 3.5 lb/in, for example, in the range of 2.5-6 lb/in, or 2.5-5 lb/in, or 2.5-4.5 lb/in, or 3-6 lb/in, or 3-5 lb/in, or 3-4.5 lb/in, or 3.5-6 lb/in, or 3.5-5 lb/in, or 3.5-4.5 lb/in). In various embodiments, the laminate has a Tg as measured by DMA in the range of 180-240° C., e.g., 180-230° C., or 180-220° C., or 190-240° C., or 190-230° C., or 190-220° C.

Various aspects and embodiments of the disclosure are further provided by the following non-limiting examples.

### Example 1

Various aspects and embodiments of the disclosure are further provided by the following non-limiting examples.

Three example formulations (A-C) included the following components, on a solids basis:

| Component | A (wt %) | B (wt %) | C (wt %) |
|---|---|---|---|
| Biphenyl epoxy resin | 6.5 | 8.5 | 10.5 |
| Maleimide oligomer | 6.5 | 4.5 | 2.5 |
| Phenol novolac epoxy resin | 5.5 | 5.5 | 5.5 |
| Styrene Maleic Anhydride | 13 | 15 | 17 |
| Benzoxazine Prepolymer | 13 | 11 | 9 |
| Phosphorus-modified phenolic resin | 7.5 | 5.5 | 3.5 |
| Halogen-free flame retardant | 12 | 9 | 6 |
| Microparticulate spherical silica | 35 | 40 | 45 |
| Silane coupling agent | 0.70 | 0.70 | 0.70 |
| Tertiary amine catalyst + | 0.15 | 0.15 | 0.15 |
| phosphonium catalyst | | | |
| Aromatic primary diamine | 0.15 | 0.15 | 0.15 |

The biphenyl epoxy resin was KES-7370, available from Kolon Industries, having the generic structure

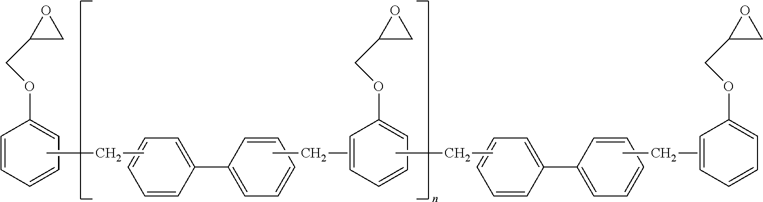

in which a number-average value of n is about 3.7.

The phenol novolac epoxy resin was PNE-177 (Chung Chen Petrochemicals), having the generic structure below:

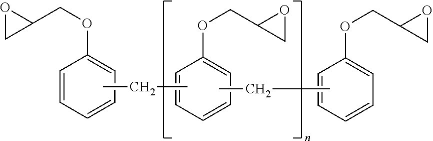

and having an epoxy equivalent weight (g/eq) of 172-182 and a viscosity of 20000-80000 cps at 52° C. when neat.

The maleimide oligomer had the general structure

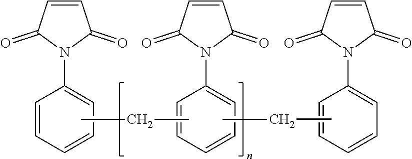

in which in is about 6 on a number-average basis. Such a product is available from Sichuan EM Technology Co., Ltd. under the designation DFE-950.

The aromatic primary diamine was 4,4′-diaminodiphenyl sulfone.

Two styrene-maleic anhydride copolymers were used, XIRAN® EF30 and XIRAN® EF40, available from Polyscope, which respectively have molar styrene:maleic anhydride ratios of 3:1 and 4:1.

The benzoxazine prepolymer was LZ-8298, available from Huntsman.

The phosphorus-modified phenolic resin KIG-G800 from Kolon Industries.

The halogen-free flame retardant was xylylene diphenylphosphine oxide.

The microparticulate spherical silica was DQ-1028L, available from Novoray.

The silane coupling agent was (3-glycidyloxypropyl)trimethoxysilane.

The catalysts were 2-phenylimidazole and tetrabutylphosphonium acid acetate.

The thermosetting compositions were formed into 6-ply laminates. The thermosetting composition was charged into a dip pan, and woven glass fabric (2116, E-glass, 0.8 mm thick, 105 g/m²) was drawn through the dip pan and then between rollers having 0.012 gap thickness. The resin-coated glass fabric was dried in an oven to substantially remove solvent (i.e., less than 1% solvent remaining). This provided a prepreg material with 57% resin on glass, about 0.005” in thickness.

Six layers of this prepreg were plied up between two sheets of copper (Very Low Profile Copper VLP grade, super flat profile, “0.5 oz,” 17 microns nominal thickness), with the treated side of the copper contacting the prepreg material, and the assembly was then placed between two stainless steel press platens, and loaded into a hot oil vacuum press. Pressure (200-500 psi) and vacuum (2-5 mbar) were applied, and the temperature of the load is brought to the dwell temp (210° C.) at a defined heat rise rate (2.5° C./min) and held there for a defined time (120 min), after which the press was allowed to cool at about 5° C./min, until the resulting laminate is cool enough to remove.

Data are provided in the Table below:

| Property | Test method | A | | B | | C | |
|---|---|---|---|---|---|---|---|
| Tg (by TMA) | IPC-TM-650 2.4.25 | 195° | C. | 191° | C. | 184° | C. |
| Tg (by DMA) | IPC-TM-650 2.4.24.4 | 220° | C. | 210° | C. | 200° | C. |
| CTE: α1 (z-axis) | IPC TM-650 2.4.24.5 | 45 | ppm/° C. | 38 | ppm/° C. | 30 | ppm/° C. |
| CTE: α2 (z-axis) | IPC TM-650 2.4.24.5 | 190 | ppm/° C. | 175 | ppm/° C. | 160 | ppm/° C. |
| Td 5% (by TGA) | IPC-TM-650 2.4.24.6 | 380° | C. | 388° | C. | 395° | C. |
| Time to delamination | IPC TM-650 2.4.24.1 | 60 | min | 60 | min | 60 | min |
| (288° C.) | | | | | | | |
| Time to delamination | IPC TM-650 2.4.24.1 | 60 | min | 60 | min | 60 | min |
| (300° C.) | | | | | | | |
| Dk | IPC TM-650 2.5.5.9 | 3.8 | | 3.9 | | 4.0 | |
| Df | IPC TM-650 2.5.5.9 | 0.0065 | | 0.0060 | | 0.0055 | |
| Peel strength ½ oz VLP | IPC-TM-650 2.4.8 | 4.00 | lb/in | 3.80 | lb/in | 3.50 | lb/in |

| Water Absorption | IPC-TM-650 2.6.2.1A | 0.12% | 0.12% | 0.12% |
|---|---|---|---|---|
| Flammability | UL94VO | V0 | V0 | V0 |

A Nokia MRT-6 test vehicle printed circuit board made with a laminate based on formulation A passed 1000 hours of conductive anode filament testing at 65° C. and 87% relative humidity, under a voltage of 100 V, for both 16 mil and 20 mil hole-to-hole spacings. It also passed 2000 cycles of interconnect stress tests for 2000 cycles at 150° C. The test vehicle also passed thermal reliability testing for both 0.65 mm and 0.80 mm pitches after both 6 cycles of reflow and six cycles of thermal stress, demonstrating excellent reliability.

Various aspects and embodiments of the disclosure are further provided by the following non-limiting embodiments, which may be combined in any number and in any combination not technically or logically inconsistent.

Embodiment 1. A thermosetting composition comprising:
an aromatic epoxy resin component, present in a total amount in the range of 5-25 wt %;
a poly(styrene-co-maleic anhydride) component, in an amount in the range of 8-30 wt %;
a maleimide-bearing oligomer component, in an amount in the range of 2-10 wt %, the maleimide-bearing oligomer component having an number-average of at least 3 maleimides per molecule, on a number average, and a softening point of no more than 100° C.;
a benzoxazine/maleimide component, that is a bis(benzoxazine) subcomponent and a bis(maleimide) subcomponent, and/or a reaction product thereof, present in an amount in the range of 2-20 wt %;
an aromatic primary diamine component, present in an amount of 0.1-2 wt %;
microparticulate silica, in an amount in the range of 15-50 wt %;
an organic halogen-free fire retardant component, in an amount of 3-25 wt %; and
an effective amount of one or more catalysts.
   Embodiment 2. The thermosetting composition of embodiment 1, wherein the aromatic epoxy resin component is present in an amount in the range of 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %.
   Embodiment 3. The thermosetting composition of embodiment 1, or embodiment 2, wherein the aromatic epoxy resin component is substantially halogen-free (e.g., no more than 1 wt % halogen, or no more than 0.5 wt % halogen).
   Embodiment 4. The thermosetting composition of any of embodiments 1-3, wherein the aromatic epoxy resin component has an aromatic carbon fraction of at least 60%, e.g., at least 65%.
   Embodiment 5. The thermosetting composition of any of embodiments 1-3, wherein the aromatic epoxy resin component has an aromatic carbon fraction of at least 70%, e.g., at least 75%.
   Embodiment 6. The thermosetting composition of any of embodiments 1-3, wherein the aromatic epoxy resin component has an aromatic carbon fraction in the range of 60-85%, e.g., 65-85%, or 60-82%, or 65-82%, or 60-80%, or 65-80%, or 60-75%, or 65-75%.
   Embodiment 7. The thermosetting composition of any of embodiments 1-3, wherein the aromatic epoxy resin component has an aromatic carbon fraction in the range of 70-85%, e.g., 75-85%, or 70-82%, or 75-82%, or 70-80%, or 75-80%.
   Embodiment 8. The thermosetting composition of any of embodiments 1-7, wherein the aromatic epoxy resin component comprises one or more of a novolac type epoxy resin (e.g., a biphenyl novolac epoxy resin, a phenol novolac epoxy resin, a cresol novolac epoxy resin), a bisphenol epoxy resin (e.g., a bisphenol A epoxy resins, a bisphenol F epoxy resins, and a bisphenol S epoxy resin), a biphenyl epoxy resin, a xylylene epoxy resin, an aryl alkylene epoxy resin (e.g., a phenol aralkyl epoxy resins, a biphenyl aralkyl epoxy resin, biphenyl novolac epoxy resins, a biphenyl dimethylene epoxy resin, a trisphenol methane novolac epoxy resin, and a tetramethyl biphenyl epoxy resin); and a naphthalene epoxy resin.
   Embodiment 9. The thermosetting composition of any of embodiments 1-8, wherein the aromatic epoxy resin component includes a biphenyl novolac epoxy resin.
   Embodiment 10. The thermosetting composition of any embodiment 9, wherein the biphenyl novolac epoxy resin has the structure

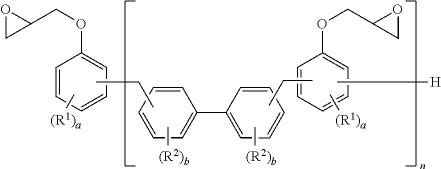

wherein each R1 and R2 is independently alkyl having 1 to 4 carbon atoms; a is in the range of 0 to 3, b is in the range of 0 to 4; and n has a number-average value in the range of 1-6.
Embodiment 11. The thermosetting composition of embodiment 10, wherein n has a number-average value in the range of 2-6, or 3-6, or 1-5, or 2-5, or 3-5.
Embodiment 12. The thermosetting composition of embodiment 10 or embodiment 11, wherein each R¹ and R² is independently methyl or ethyl and each a and b is independently 0, 1 or 2.
Embodiment 13. The thermosetting composition of embodiment 10 or embodiment 11, wherein each a and b is 0.
Embodiment 14. The thermosetting composition of embodiment 10 or embodiment 11, wherein the biphenyl novolac epoxy resin has the structure

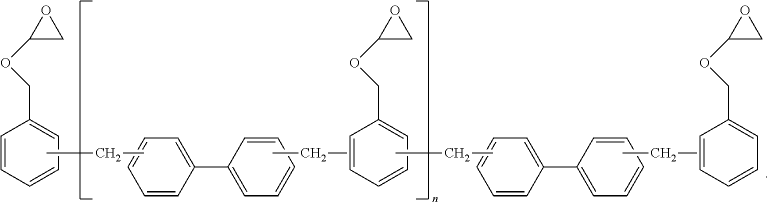

Embodiment 15. The thermosetting composition of any of embodiments 9-14, wherein the at least one biphenyl novolac epoxy resin is present in an amount in the range of 5-25 wt %, e.g., 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %.
Embodiment 16. The thermosetting composition of any of embodiments 1-15, wherein the aromatic epoxy resin component includes a phenol novolac epoxy resin.
Embodiment 17. The thermosetting composition of embodiment 16, wherein the phenol novolac epoxy has the structure

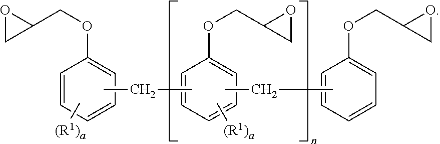

in which each R¹ is independently alkyl having 1 to 4 carbon atoms; a is in the range of 0 to 3, and n has a number-average value in the range of 1-6.
Embodiment 18. The thermosetting composition of embodiment 17, wherein n is 2-6, or 3-6, or 1-5, or 2-5, or 3-5).
Embodiment 19. The thermosetting composition of embodiment 17 or embodiment 18, wherein each R¹ is independently methyl or ethyl and each a is independently 0, 1 or 2.
Embodiment 20. The thermosetting composition of embodiment 17 or embodiment 18, wherein each a is 0.
Embodiment 21. The thermosetting composition of any of embodiments 16-20, wherein the phenol novolac epoxy is present in an amount in the range of 5-25 wt %, e.g., 5-20 wt %, or 5-17 wt %, or 5-15 wt %, or 7-25 wt %, or 7-17 wt %, or 7-15 wt %, or 10-25 wt %, or 10-20 wt %, or 10-17 wt %, or 10-15 wt %.
Embodiment 22. The thermosetting composition of any of embodiments 16-20, wherein the phenol novolac epoxy is present in an amount in the range of 1-10 wt %, e.g., 1-7 wt %, or 1-5 wt %, or 2-10 wt %, or 2-7 wt %, or 2-5 wt %, or 3-10 wt %, or 3-7 wt %, or 3-5 wt %.
Embodiment 23. The thermosetting composition of any of embodiments 1-22, wherein the aromatic epoxy resin component includes a biphenyl novolac epoxy as described in any of embodiments 9-12 and a phenol novolac epoxy as described in any of embodiments 13-16.
Embodiment 24. The thermosetting composition of embodiment 23, wherein a weight ratio of biphenyl novolac epoxy resin to phenol novolac epoxy resin is in the range of 1:1 to 15:1, e.g., 2:1 to 10:1, or 2:1 to 5:1, or 2:1 to 3:1.
Embodiment 25. The thermosetting composition of any of embodiments 1-24, wherein the aromatic epoxy resin component has an epoxy equivalent value in the range of 150 g/eq to 350 g/eq.
Embodiment 26. The thermosetting composition according to any of embodiments 1-25, wherein an amount of any non-aromatic epoxy resins is no more than 10 wt %, e.g., no more than 5 wt %, or no more than 2 wt %, or no more than 1 wt %.
Embodiment 27. The thermosetting composition according to any of embodiments 1-26, wherein the poly(styrene-co-maleic anhydride) component is present in an amount in the range of 8-25 wt %, or 8-22 wt %, or 8-20 wt %, or 8-18 wt %, or 10-30 wt %, or 10-25 wt %, or 10-22 wt %, or 10-20 wt %, or 10-18 wt %.
Embodiment 28. The thermosetting composition according to any of embodiments 1-26, wherein the poly(styrene-co-maleic anhydride) component is present in an amount in the range of 12-30 wt %, e.g., 12-25 wt %, or 12-22 wt %, or 12-20 wt %, or 12-18 wt %, or 14-30 wt %, or 14-25 wt %, or 14-22 wt %, or 14-20 wt %, or 14-18 wt %.
Embodiment 29. The thermosetting composition according to any of embodiments 1-28, wherein the poly(styrene-co-maleic anhydride) component has no more than 5 wt % or residues that are not styrene residues or maleic anhydride residues, e.g., no more than 2 wt %, or no more than 1 wt %.
Embodiment 30. The thermosetting composition according to any of embodiments 1-29, wherein the poly(styrene-co-maleic anhydride) component has a ratio of styrene to maleic anhydride residues in the range of 2:1-6:1, e.g., 2:1-5:1, or 2:1-4:1, or 2.5:1-6:1, or 2.5:1-5:1, or 2.5:1-4:1, or 3:1-6:1, or 3:1-5:1, or 3:1-4:1.
Embodiment 31. The thermosetting composition according to any of embodiments 1-29, wherein the poly(styrene-co-maleic anhydride) component has a ratio of styrene to maleic anhydride residues in the range of 3:1-4:1.
Embodiment 32. The thermosetting composition according to any of embodiments 1-31, wherein the poly(styrene-co-maleic anhydride) component comprises (or is) a blend of a first poly(styrene-co-maleic anhydride) polymer having a ratio of styrene to maleic anhydride residues in the range of 2.8:1-3.2:1, and a second poly(styrene-co-maleic anhydride) polymer having a ratio of styrene to maleic anhydride residues in the range of 3.8:1-4.2:1.
Embodiment 33. The thermosetting composition according to any of embodiments 1-32, wherein the maleimide-bearing oligomer component is present in an amount in the range of 2-9 wt %, or 2-7 wt %, or 3-10 wt %, or 3-9 wt %, or 3-7 wt %, or 5-10 wt %, or 5-9 wt %, or 5-7 wt %.
Embodiment 34. The thermosetting composition according to any of embodiments 1-33, wherein the maleimide-bearing oligomer component has at least 4 maleimides per molecule, e.g., at least 5, or at least 6, on number average.
Embodiment 35. The thermosetting composition according to any of embodiments 1-33, wherein the maleimide-bearing oligomer component has in the range of 3-10 maleimides per molecule, e.g., in the range of 4-10, or 5-10, or 6-10, or 3-9, or 4-9, or 5-9, or 6-9, on number average.
Embodiment 36. The thermosetting composition according to any of embodiments 1-33, wherein the maleimide-bearing oligomer component has in the range of 3-8 maleimides per molecule, e.g., in the range of 4-8, or 5-8, or 6-8, or 3-7, or 4-7, or 5-7, on number average.
Embodiment 37. The thermosetting composition according to any of embodiments 1-36, wherein the maleimide-bearing oligomer component has a softening point of no more than 95° C., e.g., no more than 90° C.
Embodiment 38. The thermosetting composition according to any of embodiments 1-36, wherein the maleimide-bearing oligomer component has a softening point in the range of 70-100° C., e.g., 75-100° C., or 80-100° C., or 70-95° C., or 75-95° C., or 80-95° C., or 70-90° C., or 75-90° C., or 80-90° C., or 70-85° C., or 75-85° C., or 80-85° C.
Embodiment 39. The thermosetting composition according to any of embodiments 1-38, wherein the maleimide-bearing oligomer component an aromatic carbon fraction of at least 80%, e.g., at least 84%, or at least 88%.
Embodiment 40. The thermosetting composition according to any of embodiments 1-39, wherein the maleimide-bearing oligomer component has the structure

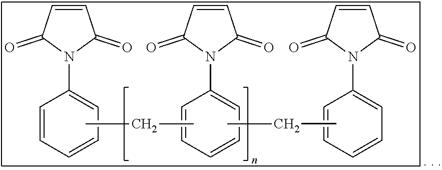

Embodiment 41. The thermosetting composition according to any of embodiments 1-40, wherein the benzoxazine/maleimide component is present in an amount in the range of 2-17 wt %, or 2-15 wt %, or 2-12 wt %, or 2-9 wt %, or 4-20 wt %, or 4-17 wt %, or 4-15 wt %, or 4-12 wt %, or 4-9 wt %, or 6-20 wt %, or 6-17 wt %, or 6-15 wt %, or 6-12 wt %, or 6-9 wt %.
Embodiment 42. The thermosetting composition according to any of embodiments 1-41, wherein the bis(benzoxazine) subcomponent comprises (or is) one or more of the following:

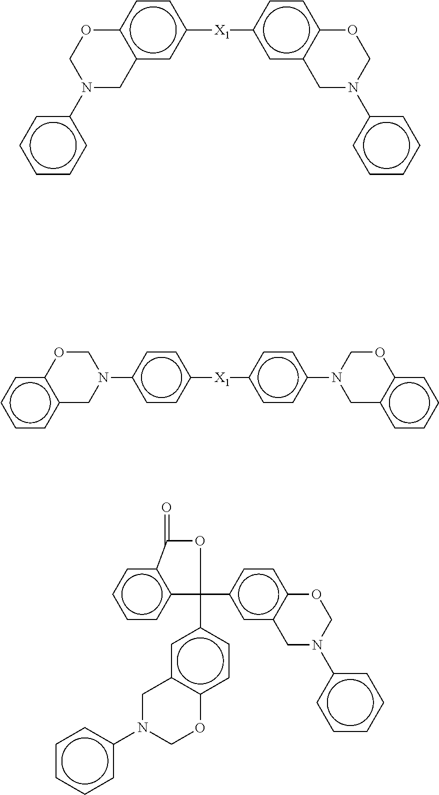

in which each of X₁ and X₂ is independently an arylene (e.g., phenylene, biphenylene, naphthylene); C₁-C₃ alkylene (desirably substituted at the same carbon, such as —C(CH₃)₂—, —CH(CH₃)—, —CH₂—), or S(O)₀₋₂.
Embodiment 43. The thermosetting composition according to any of embodiments 1-42, wherein the bis(benzoxazine) subcomponent of the benzoxazine/maleimide component comprises (or is) one or more of

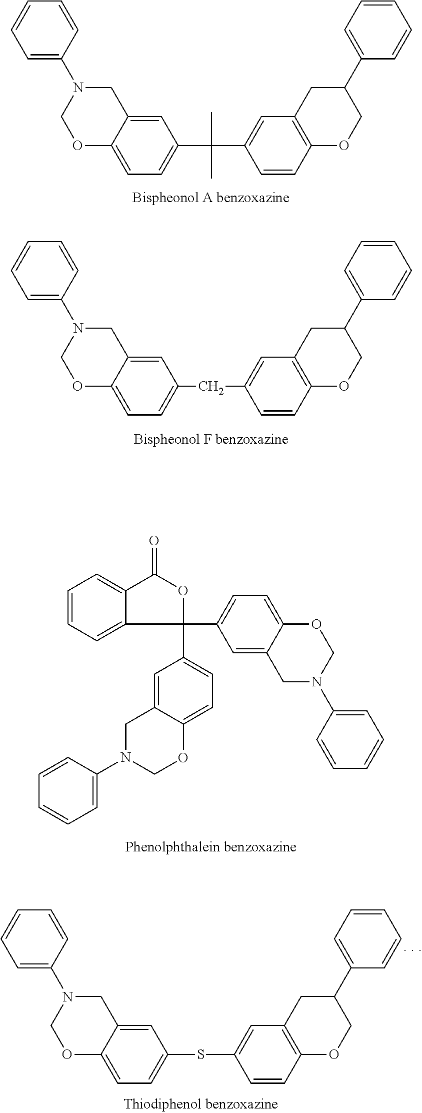 [SMILES: CC(C)(c1ccc2c(c1)CC(c1ccccc1)CO2)c1ccc2c(c1)CN(c1ccccc1)CO2 ; c1ccc(C2COc3ccc(Cc4ccc5c(c4)CN(c4ccccc4)CO5)cc3C2)cc1 ; O=C1OC(c2ccc3c(c2)CN(c2ccccc2)CO3)(c2ccc3c(c2)CN(c2ccccc2)CO3)c2ccccc21 ; c1ccc(C2COc3ccc(Sc4ccc5c(c4)CN(c4ccccc4)CO5)cc3C2)cc1]

Embodiment 44. The thermosetting composition according to any of embodiments 1-42, wherein the bis(maleimide) subcomponent comprises (or is) one or more of 4,4′-bismaleimidodiphenylmethane, bis(3-ethyl-5-methyl-4-maleimidophenyl)methane, 2,2-bis[4-(4-maleimidophenoxy)phenyl]propane, m-phenylenebismaleimide, 4-methyl-1,3-phenylene bismaleimide and N,N′-1,4-phenylenedimaleimide.
Embodiment 46. The thermosetting composition according to any of embodiments 1-45, wherein the bis(maleimide) subcomponent comprises (or is) 4,4′-bismaleimidodiphenylmethane
Embodiment 47. The thermosetting composition according to any of embodiments 1-46, wherein the benzoxazine/maleimide component is provided as a prepolymer of the bis(benzoxazine) subcomponent and the bismaleimide subcomponent (e.g., a bisphenol F benzoxazine/4,4′-bismaleimidodiphenylmethane prepolymer).
Embodiment 48. The thermosetting composition according to any of embodiments 1-47, wherein a molar ratio of the bis(benzoxazine) subcomponent to the bis(maleimide) subcomponent is in the range of 2:1 to 1:2, e.g., in the range of 1.5:1 to 1:2, or 1.25:1 to 1:2, or 1:1 to 1:2, or 2:1 to 1:1.5, or 1.5:1 to 1:1.5, or 1.25:1 to 1:1.5, or 1:1 to 1:1.5, or 2:1 to 1:1.25, or 1.5:1 to 1:1.25, or 1.25:1 to 1:1.25, or 1:1 to 1:1.25, or 2:1 to 1:1, or 1.5:1 to 1:1, or 1.25:1 to 1:1 Embodiment 49. The thermosetting composition according to any of embodiments 1-47, wherein a molar ratio of the bis(benzoxazine) subcomponent to the bis(maleimide) subcomponent is in the range of 9:1 to 2:1, e.g., 7:1 to 2:1, or 5:1 to 2:1, or 4:1 to 2:1.
Embodiment 50. The thermosetting composition according to any of embodiments 1-47, wherein a molar ratio of the bis(benzoxazine) subcomponent to the bis(maleimide) subcomponent is in the range of 1:9 to 1:2, e.g., 1:7 to 1:2, or 1:5 to 1:2, or 1:4 to 1:2.
Embodiment 51. The thermosetting composition according to any of embodiments 1-50, wherein the benzoxazine/maleimide component has an aromatic carbon content of at least 60%, e.g., at least 65%, or at least 67%, or at least 70%.
Embodiment 52. The thermosetting composition according to any of embodiments 1-51, wherein the aromatic primary diamine component is present in an amount of 0.1-1.5 wt %, or 0.1-1 wt %, or 0.1-0.7 wt %, or 0.2-2 wt %, or 0.2-1.5 wt %, or 0.2-1 wt %, or 0.2-0.7 wt %.
Embodiment 53. The thermosetting composition according to any of embodiments 1-52, wherein the aromatic primary diamine component comprises (or is) 4,4′-(diaminodiphenyl)sulfone, 4,4′-diaminodiphenyl(ether), or 4,4′-diaminodiphenyl(methane).
Embodiment 54. The thermosetting composition according to any of embodiments 1-53, wherein the aromatic primary diamine component comprises (or is) 4,4′-(diaminodiphenyl)sulfone.
Embodiment 55. The thermosetting composition of any of embodiments 1-54, wherein the aromatic primary diamine component has an aromatic carbon content of at least 90%, e.g., at least 95% or at least 98% or at least 99%.
Embodiment 56. The thermosetting composition of any of embodiments 1-55, wherein the microparticulate silica has a d₅₀ particle size in the range of 0.5-10 microns, e.g., 0.5-7 microns, or 0.5-5 microns, or 1-10 microns, or 1-7 microns, or 1-5 microns.
Embodiment 57. The thermosetting composition of any of embodiments 1-56, wherein the microparticulate silica has a d₉₀ particle size in the range of 1-20 microns, e.g., 1-14 microns, or 1-8 microns, or 3-20 microns, or 3-14 microns, or 3-8 microns.
Embodiment 58. The thermosetting composition of any of embodiments 1-57, wherein the microparticulate silica has a d₁₀ particle size in the range of 0.1-5 microns, e.g., 0.1-3 microns, or 0.1-2 microns, or 0.5-5 microns, or 0.5-3 microns, or 0.5-2 microns.
Embodiment 59. The thermosetting composition of any of embodiments 1-58, wherein the microparticulate silica is substantially spherical.
Embodiment 60. The thermosetting composition of any of embodiments 1-59, wherein the microparticulate silica has at least 99 wt % SiO₂, e.g., at least 99.5 wt % SiO₂.
Embodiment 61. The thermosetting composition of any of embodiments 1-60, wherein the microparticulate silica is present in an amount in the range of 15-45 wt %, or 15-40 wt %, or 15-35 wt %.
Embodiment 62. The thermosetting composition of any of embodiments 1-60, wherein the microparticulate silica is present in an amount in the range of 20-50 wt %, e.g., 20-45 wt %, or 20-40 wt %, or 20-35 wt %.
Embodiment 63. The thermosetting composition of any of embodiments 1-60, wherein the microparticulate silica is present in an amount in the range of 20-50 wt %, e.g., 25-45 wt %, or 25-40 wt %, or 25-35 wt % Embodiment 64. The thermosetting composition of any of embodiments 1-63, wherein the organic halogen-free fire-retardant component is a fire retardant as described in any of U.S. Pat. Nos. 8,536,256, 9,012,546, 9,522,927 and 9,562,063.
Embodiment 65. The thermosetting composition of any of embodiments 1-63, wherein the organic halogen-free fire retardant component includes (or is) 6H-Dibenz[c,e][1,2]oxaphosphorine, 6,6′-(1,4-ethanediyl)bis-, 6,6′-dioxide; 6H-Dibenz[c,e][1,2]oxaphosphorine, 6,6′-(1,4-butanediyl)bis-,6,6′-dioxide; or 6H-Dibenz[c,e][1,2]oxaphosphorine, 6,6′-(p-xylenediyl)bis-,6,6′-dioxide; or any combination thereof.
Embodiment 66. The thermosetting composition of any of embodiments 1-63, wherein the organic halogen-free fire retardant component includes (or is) is 6H-Dibenz[c,e][1,2]oxaphosphorin, 6,6′-(1,4-ethanediyl)bis-, 6,6′-dioxide.
Embodiment 67. The thermosetting composition of any of embodiments 1-63, wherein the organic halogen-free fire retardant component includes (or is) a compound having the structure: having the following structure:

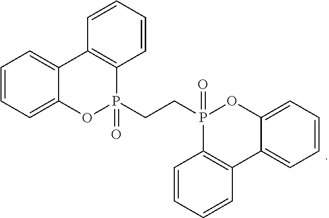 [SMILES: O=P1(CCP2(=O)Oc3ccccc3-c3ccccc32)Oc2ccccc2-c2ccccc21]

Embodiment 68. The thermosetting composition of any of embodiments 1-63, wherein the organic halogen-free fire retardant component includes (or is) composition comprising the high melting point isomer of Formula IIa:

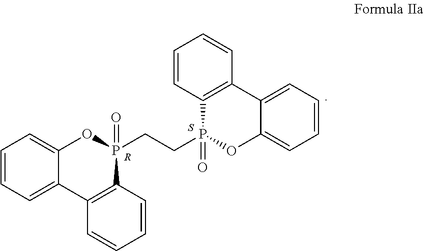

and the low melting point isomers of Formula IIb and IIc having the Formulas:

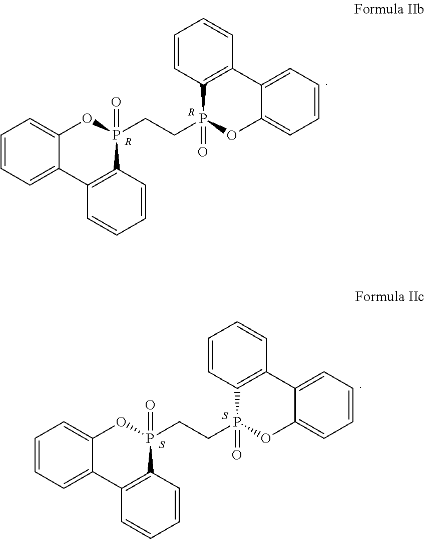

wherein said composition has an Isomer Ratio of greater than about 0.5 utilizing the 31P NMR method and wherein said Isomer Ratio=Aₕ/(Aₕ+Aᵢ), wherein Aₕ: area of high melting point isomer peak and Aᵢ: area of low melting point isomers peak.
Embodiment 69. The thermosetting composition of any of embodiments 1-68, wherein the organic halogen-free fire retardant component comprises (or is) a diaryl phosphine oxide-based fire retardant.
Embodiment 70. The thermosetting composition of any of embodiments 1-68, wherein the organic halogen-free fire retardant component comprises (or is) a diphenyl phosphine oxide-based fire retardant
Embodiment 71. The thermosetting composition of any of embodiments 1-68, wherein the organic halogen-free fire retardant component comprises (or is) a compound of the structural formula

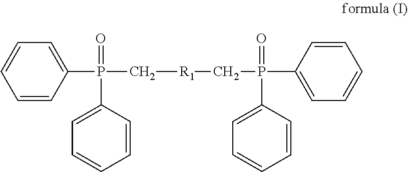

wherein R₁ is selected from the group consisting of a covalent bond, —CH₂—,

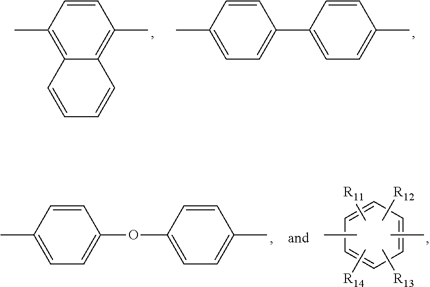

in which R₁, R₁₂, R₁₃, and R₁₄ are independently H, alkyl, or

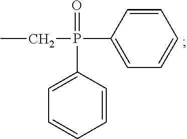 [SMILES: CCP(=O)(c1ccccc1)c1ccccc1]

Embodiment 72. The thermosetting composition of any of embodiments 1-68, wherein the organic halogen-free fire retardant component comprises (or is) a compound of the structural formula

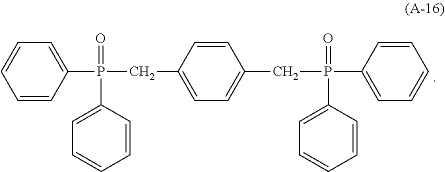 [SMILES: O=P(Cc1ccc(CP(=O)(c2ccccc2)c2ccccc2)cc1)(c1ccccc1)c1ccccc1]

Embodiment 73. The thermosetting composition according to any of embodiments 1-72, wherein the organic halogen-free fire retardant component is present in an amount of 3-20 wt %, e.g., 3-15 wt %.
Embodiment 74. The thermosetting composition according to any of embodiments 1-72, wherein the organic halogen-free fire retardant component is present in an amount of 4-25 wt %, e.g., 4-20 wt %, or 4-15 wt %.
Embodiment 75. The thermosetting composition according to any of embodiments 1-72, wherein the organic halogen-free fire retardant component is present in an amount of 5-25 wt %, e.g., 5-20 wt %, or 5-15 wt %.
Embodiment 76. The thermosetting composition according to any of embodiments 1-75, wherein the one or more catalysts includes a tertiary amine catalyst, e.g., an N-substituted imidazole catalyst such as 2-phenylimidazole, 2-methylimidazole, or 2-ethylimidazole.
Embodiment 77. The thermosetting composition according to any of embodiments 1-76, wherein the one or more catalysts includes a phase transfer catalyst, such as a salt of a quaternary phosphonium or a quaternary ammonium, e.g., a tetraalkylphosphonium salt (such as tetrabutylphosphonium acetate); a tetraalkylammonium salt or a benzyltrialkylammonium salt.
Embodiment 78. The thermosetting composition according to any of embodiments 1-77, wherein the effective amount of the one or more catalysts is in the range of 0.005-1 wt %, e.g., 0.005-0.5 wt % or 0.005-0.2 wt %, or 0.005-0.1 wt %, or 0.01-1 wt %, or 0.01-0.5 wt %, or 0.01-0.2 wt %, or 0.01-0.1 wt %.
Embodiment 79. The thermosetting composition according to any of embodiments 1-77, further comprising a phosphorus-modified phenolic resin in an amount in the range of up to 15 wt %, e.g., up to 10 wt %, or up to 8 wt %.
Embodiment 80. The thermosetting composition according to embodiment 77, wherein the phosphorus-modified phenolic resin is present in an amount in the range of 3-15 wt %, e.g., 3-10 wt %, or 3-8 wt %, or 5-15 wt %, or 5-10 wt %, or 5-8 wt %.
Embodiment 81. The thermosetting composition according to embodiment 77 or embodiment 80, wherein the phosphorus-modified phenolic resin has the structure

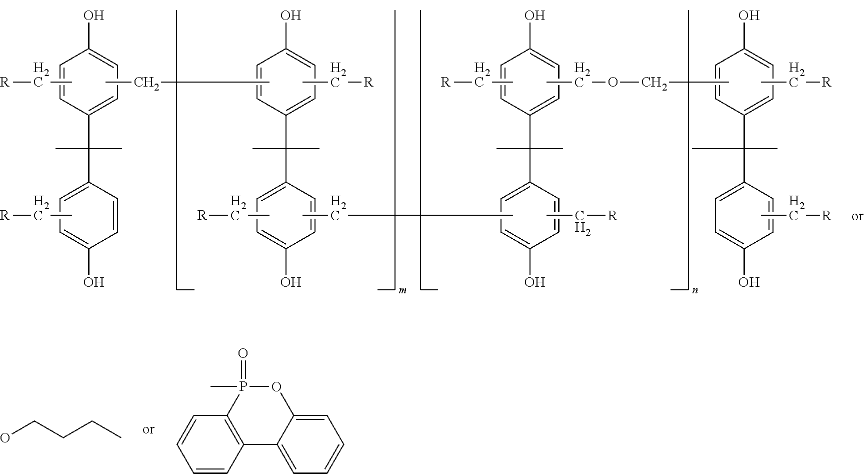

in which each R is independently one of the structures at the right of the diagram and m is, e.g., in the range of 1-100.
Embodiment 82. The thermosetting composition according to any of embodiments 1-81, further comprising an epoxy-functional or amine-functional silane, in an amount up to 2 wt %, e.g., up to 1.5 wt %, or up to 1 wt %.
Embodiment 83. The thermosetting composition according to embodiment 82, wherein the epoxy-functional or amine-functional silane is present in an amount in the range of 0.1-2 wt %, e.g., 0.1-1.5 wt %, or 0.1-1 wt %, or 0.2-2 wt %, or 0.2-1.5 wt %, or 0.2-1 wt %.
Embodiment 84. The thermosetting composition according to embodiment 82 or embodiment 83, wherein the epoxy-functional or amine-functional silane is a C₁-C₃ alkoxy silane, e.g., a methoxysilane or an ethoxysilane, such as a trimethoxysilane or a triethoxysilane.
Embodiment 85. The thermosetting composition according to any of embodiments 82-84, wherein the epoxy-functional or amine-functional silane comprises (or is) an epoxy-functional silane such as (3-glycidyloxypropyl)trimethoxysilane or (3-glycidyloxypropyl)triethoxysilane.
Embodiment 86. The thermosetting composition according to any of embodiments 82-84, wherein the epoxy-functional or amine-functional silane comprises (or is) an amino-functional silane, such as (3-aminopropyl)trimethoxysilane or (3-aminopropyl)triethoxysilane.
Embodiment 87. The thermosetting composition according to any of embodiments 1-86, provided in substantially non-volatile form, i.e., without a substantial amount of a solvent.
Embodiment 88. The thermosetting composition according to any of embodiments 1-87, comprising no more than 10 wt % material having a boiling point at atmospheric pressure of less than 200° C., e.g., no more than 5 wt %, or no more than 3 wt %, or no more than 1 wt %, all calculated with the non-volatile content being 100 wt %.
Embodiment 89. The thermosetting composition according to any of embodiments 1-88, further comprising a solvent having a boiling point at atmospheric pressure of less than 200° C.
Embodiment 90. The thermosetting composition according to embodiment 89, wherein the solvent is one or more of y-butyrolactone, cyclohexanone, butanone, methyl isobutyl ketone, N,N-dimethylformamide, propylene glycol monomethyl ether, N,N-dimethylacetamide, ethylene glycol monomethyl ether, methoxy ethyl acetate, ethoxy ethyl acetate, propoxy ethyl acetate, diisobutyl ketone (DIBK), N-methyl-pyrrolidone, xylene, ethyl acetate, toluene, trichloroethane, dibutyl ether, methyl ethyl ketone, and acetone.
Embodiment 91. The thermosetting composition according to embodiment 89 or embodiment 90, wherein an amount of solvent is in the range of 20-60 wt % in excess of the non-volatile components of the thermosetting composition (i.e., taken together as 100 wt %).
Embodiment 92. A cured product of a thermosetting composition according to any of embodiments 1-91.
Embodiment 93. A method for curing the thermosetting composition according to any of embodiments 1-91, comprising heating the thermosetting composition at a temperature effective to at least partially cure the composition, e.g., 150-250° C.
Embodiment 94. A prepreg comprising a mesh substrate at least partially embedded in a cured product of embodiment 92 or a cured product made by the method of embodiment 93.
Embodiment 95. The prepreg according to embodiment 94, wherein the cured product is a partially-cured product.
Embodiment 96. The prepreg according to embodiment 94 or embodiment 95, wherein, the mesh substrate is a fabric (woven or non-woven).
Embodiment 97. The prepreg according to embodiment 96, wherein the fabric made from glass fiber, e.g., as a borosilicate glass fabric.
Embodiment 98. The prepreg according to embodiment 96 or embodiment 97 wherein, the mesh substrate is electronic grade E-glass fabric, NE-glass fabric, D-glass fabric, or S-glass fabric.
Embodiment 99. The prepreg according to any of embodiments 94-98, that is in the range of 10-300 microns in thickness, e.g., 10-200 microns, or 10-150 microns, or 10-100 microns.
Embodiment 100. The prepreg according to any of embodiments 94-98, that is in the range of 25-300 microns in thickness, e.g., 25-200 microns, or 25-150 microns, or 25-100 microns.
Embodiment 101. The prepreg according to any of embodiments 94-98, that is in the range of 50-300 microns in thickness, e.g., 50-200 microns, or 50-150 microns.
Embodiment 102. The prepreg according to any of embodiments 94-101, comprising at least 30 wt % of the cured product of the disclosure, e.g., at least 50 wt %.
Embodiment 103. A laminate of a plurality of prepregs according to any of embodiments 94-102.
Embodiment 104. A laminate according to embodiment 103, wherein the cured product of the prepregs in the laminate is substantially fully cured.
Embodiment 105. A laminate according to embodiment 103 or embodiment 104, further comprising one or more layers of metal, e.g., at one or more opposing major surfaces of the laminate.
Embodiment 106. A laminate according to embodiment 105, wherein the one or more layers of metal are layers of copper.
Embodiment 107. A laminate according to embodiment 106, wherein the one or more layers of copper are in the range of 15-50 microns in thickness, e.g., in the range of 17-37 microns in thickness.
Embodiment 108. A laminate according to embodiment 106 or embodiment 107, wherein each of the one or more layers of copper have an outer surface facing away from the prepreg to which the layer is laminated, having one or more of a surface roughness Ra (measured by contact, ISO 4287) of no more than 0.3 microns, and/or a surface roughness Sa (measured contactless, ISO 25178) in the range of 0.1-0.3 microns, e.g., 0.15-0.25 microns.
Embodiment 109. A laminate according to any of embodiments 106-108, wherein each of the one or more layers of copper have an inner surface contacting one of the prepregs having one or more of a surface roughness Sa in the range of 0.1-0.4 microns (e.g., 0.12-0.3 microns; a surface roughness Sz in the range of 1-5 microns (e.g., 1.2-4 microns); and/or a surface roughness Sdr in the range of 0.5-3 microns (e.g., 0.7-2 microns), each measured contactless, ISO 25178).
Embodiment 110. A laminate according to any of embodiments 106-109, having a Df value of in the range of 0.003 to 0.009, e.g., 0.004 to 0.009, or 0.005-0.009 as measured by IPC-TM-650 2.5.9.
Embodiment 111. A laminate according to any of embodiments 106-110, having a Dk value in the range of 3.5 to 4.5, e.g., 3.65-4.5, 3.85-4.5, or 3.65-4.35 as measured by IPC-TM-650 2.5.5.9.
Embodiment 112. A laminate according to any of embodiments 106-111, having a Tg as measured by DMA in the range of 150-210° C., e.g., 150-195° C., or 160-210° C., or 160-195° C., or 170-210° C., or 170-195° C.

1. A thermosetting composition comprising:
an aromatic epoxy resin component, present in a total amount in the range of 5-25 wt %;
a poly(styrene-co-maleic anhydride) component, in an amount in the range of 8-30 wt %;
a maleimide-bearing oligomer component, in an amount in the range of 2-10 wt %, the maleimide-bearing oligomer component having an number-average of at least 3 maleimides per molecule, on a number average, and a softening point of no more than 100° C.;
a benzoxazine/maleimide component, that is a bis(benzoxazine) subcomponent and a bis(maleimide) subcomponent, and/or a reaction product thereof, present in an amount in the range of 2-20 wt %;
an aromatic primary diamine component, present in an amount of 0.1-2 wt %;
microparticulate silica, in an amount in the range of 15-50 wt %;
an organic halogen-free fire retardant component, in an amount of 3-25 wt %; and
an effective amount of one or more catalysts.

2. The thermosetting composition of claim 1, wherein the aromatic epoxy resin component is present in an amount in the range of 5-15 wt %.

3. The thermosetting composition of claim 1, wherein the aromatic epoxy resin component is substantially halogen-free.

4. The thermosetting composition of claim 1, wherein the aromatic epoxy resin component has an aromatic carbon fraction in the range of 70-85%.

5. The thermosetting composition of claim 1, wherein the aromatic epoxy resin component includes a biphenyl novolac epoxy resin and a phenol novolac epoxy resin.

6. The thermosetting composition of claim 5, wherein a weight ratio of biphenyl novolac epoxy resin to phenol novolac epoxy resin is in the range of 1:1 to 15:1.

7. The thermosetting composition according to claim 1, wherein an amount of any non-aromatic epoxy resins is no more than 10 wt %.

8. The thermosetting composition according to claim 1, wherein the poly(styrene-co-maleic anhydride) component is present in an amount in the range of 8-25 wt %.

9. The thermosetting composition according to claim 1, wherein the poly(styrene-co-maleic anhydride) component has no more than 5 wt % or residues that are not styrene residues or maleic anhydride residues.

10. The thermosetting composition according to claim 1, wherein the poly(styrene-co-maleic anhydride) component has a ratio of styrene to maleic anhydride residues in the range of 2:1-6:1.

11. The thermosetting composition according to claim 1, wherein the maleimide-bearing oligomer component is present in an amount in the range of 2-7 wt %.

12. The thermosetting composition according to claim 1, wherein the maleimide-bearing oligomer component has in the range of 3-10 maleimides per molecule on number average.

13. The thermosetting composition according to claim 1, wherein the maleimide-bearing oligomer component an aromatic carbon fraction of at least 80%.

14. The thermosetting composition according to claim 1, wherein the benzoxazine/maleimide component is provided as a prepolymer of the bis(benzoxazine) subcomponent and the bismaleimide subcomponent.

15. The thermosetting composition according to claim 1, wherein a molar ratio of the bis(benzoxazine) subcomponent to the bis(maleimide) subcomponent is in the range of 2:1 to 1:2.

16. The thermosetting composition according to claim 1, wherein the aromatic primary diamine component comprises 4,4′-(diaminodiphenyl)sulfone, 4,4′-diaminodiphenyl(ether), or 4,4′-diaminodiphenyl(methane).

17. The thermosetting composition of claim 1, wherein the aromatic primary diamine component has an aromatic carbon content of at least 90%.

18. The thermosetting composition according to claim 1, further comprising a phosphorus-modified phenolic resin in an amount in the range of up to 15 wt %, or further comprising an epoxy-functional or amine-functional silane, in an amount up to 2 wt %.

19. A prepreg comprising a mesh substrate at least partially embedded in a cured product of the thermosetting composition of claim 1.

20. A laminate of a plurality of prepregs according to claim 19.
